(19) United States
(12) Patent Application Publication
(10) Pub. No.: US 2021/0175083 A1
(43) Pub. Date: Jun. 10, 2021

(54) METHOD OF MANUFACTURING METAL ELECTRODE

(71) Applicant: TCL CHINA STAR OPTOELECTRONICS TECHNOLOGY CO. LTD., Shenzhen, Guangdong (CN)

(72) Inventor: Jinyang ZHAO, Shenzhen, Guangdong (CN)

(21) Appl. No.: 16/627,851

(22) PCT Filed: Dec. 19, 2019
(86) PCT No.: PCT/CN2019/126516

§ 371 Date: Dec. 31, 2019

(30) Foreign Application Priority Data
Dec. 10, 2019 (CN) 201911256841.8

(51) Int. Cl. H01L 21/288; C23C 16/455

(52) U.S. Cl. CPC H01L 21/288; C23C 16/45536

(57) ABSTRACT

A method of manufacturing a metal electrode includes following steps: providing a substrate, and using inkjet printing technology to form a metal organic layer with a predetermined pattern on the substrate. The metal organic layer is made of a material including metal organic compounds. Use plasma technology to treat the metal organic layer, so that the metal organic compounds of the metal organic layer are converted into a corresponding metal to form a metal electrode with the predetermined pattern.

This application claims the priority of China Patent Application serial No. 201911256841.8, filed Dec. 10, 2019, titled “METHOD OF MANUFACTURING METAL ELECTRODE”, the disclosures of which are incorporated herein by reference in their entirety.

### BACKGROUND OF INVENTION

### 1. Field of Invention

The present application relates to a technical field of methods of manufacturing display panels, and particularly to, a method of manufacturing a metal electrode.

### 2. Related Art

With development of technology, televisions (TV) and other display devices are also developing in directions of large-scale, high-quality, and high-functionality, so it is very important to improve product characteristics. Wiring in display devices generally uses metal electrodes. Metal electrodes play an important role in transmitting electrical signals in display devices. Metal materials with high conductivity, low impedance, and low cost are preferred materials for metal electrodes, such as copper electrodes. Because copper metal has higher electrical conductivity than that of aluminum metal, when using low-impedance metal copper as wiring material in display devices, non-impedance values of the display devices are lower than that of the display devices when using traditional metal aluminum as the wiring material. In addition, considering film thickness, metal copper is less expensive metal aluminum, so metal copper is gradually becoming main material of metal electrodes in display devices.

Currently, metal electrodes are mainly prepared by a photolithography process. The process includes physical vapor deposition (PVD) film formation, photoresist coating, photolithography, wet etching, and photoresist peeling, which are complicated, and the process is a subtractive manufacturing technology, causing more material waste. Therefore, it is of great significance to develop new methods for precision machining of metal electrodes.

### SUMMARY OF INVENTION

The present application provides a method of manufacturing a metal electrode using inkjet printing technology and plasma technology to overcome technical problems of a complicated process of manufacturing the metal electrode and waste of materials during the manufacturing process.

In one embodiment, the present application provides a method of manufacturing a metal electrode, comprising providing a substrate; forming, using inkjet printing technology, a metal organic layer with a predetermined pattern on the substrate, wherein the metal organic layer is made of a material comprising metal organic compounds; and treating, using plasma technology, the metal organic layer, so that the metal organic compounds of the metal organic layer are converted into a corresponding metal to form a metal electrode with the predetermined pattern.

In the method of manufacturing the metal electrode of the embodiment of the present application, the forming, using inkjet printing technology, a metal organic layer with a predetermined pattern on the substrate comprises printing, using an inkjet print head, a metal ink on the substrate according to a predetermined path, wherein the metal ink comprises the metal organic compounds and a solvent; and removing, by heating the substrate after printing, the solvent in the metal ink on the substrate to form the metal organic layer with the predetermined pattern.

In the method of manufacturing the metal electrode of the embodiment of the present application, the treating, using plasma technology, the metal organic layer, so that the metal organic compounds of the metal organic layer are converted into a corresponding metal comprises treating, using oxygen plasma, the metal organic layer, to decompose the metal organic compounds of the metal organic layer into the corresponding metal and oxides of the metal; and treating, using hydrogen plasma, the metal organic layer treated by the oxygen plasma, so that the oxides of the metal are reduced to form the metal.

In the method of manufacturing the metal electrode of the embodiment of the present application, the treating, using oxygen plasma, the metal organic layer, to decompose the metal organic compounds of the metal organic layer into the corresponding metal and oxides of the metal comprises placing the substrate with the metal organic layer in a vacuum chamber; providing the oxygen plasma into the vacuum chamber; and decomposing, using the oxygen plasma, the metal organic compounds of the metal organic layer into the corresponding metal and the oxides of the metal.

In the method of manufacturing the metal electrode of the embodiment of the present application, the treating, using hydrogen plasma, the metal organic layer treated by the oxygen plasma, so that the oxides of the metal are reduced to form the metal comprises stopping providing the oxygen plasma into the vacuum chamber; providing the hydrogen plasma into the vacuum chamber; and reducing, using the hydrogen plasma, the oxides of the metal to form the metal.

In the method of manufacturing the metal electrode of the embodiment of the present application, the vacuum chamber includes an inlet and an outlet, and the oxygen plasma and the hydrogen plasma enter the vacuum chamber from the inlet, wherein an organic gas is further generated when the metal organic compounds are decomposed by the oxygen plasma, and the organic gas is discharged from the outlet.

In the method of manufacturing the metal electrode of the embodiment of the present application, the forming, using inkjet printing technology, a metal organic layer with a predetermined pattern on the substrate further comprises performing, using a hydrophobic material, hydrophobic treatment on a surface of the substrate to be printed.

In the method of manufacturing the metal electrode of the embodiment of the present application, the hydrophobic material comprises perfluorosilane.

In the method of manufacturing the metal electrode of the embodiment of the present application, the metal electrode comprises a copper electrode.

In the method of manufacturing the metal electrode of the embodiment of the present application, the metal organic compounds comprise at least one of copper-based metal organic compounds and copper micro/nanoparticles coated with organic compounds.

In the method of manufacturing the metal electrode of the embodiment of the present application, the metal electrode comprises a silver electrode.

In the method of manufacturing the metal electrode of the embodiment of the present application, the metal organic compounds comprise silver micro/nanoparticles coated with organic compounds.

In the method of manufacturing the metal electrode of the embodiment of the present application, the substrate comprises one of a glass substrate, a silicon wafer substrate, and a flexible substrate.

In the method of manufacturing the metal electrode of the embodiment of the present application, the flexible substrate is made of a material comprising polyimide, polyethylene terephthalate, and polyethylene terephthalate.

In one embodiment, the present application further provides a method of manufacturing a metal electrode, comprising providing a substrate; performing, using a hydrophobic material, hydrophobic treatment on a surface of the substrate to be printed; printing, using an inkjet print head, a metal ink on the substrate according to a predetermined path, wherein the metal ink comprises metal organic compounds and a solvent; removing, by heating the substrate after printing, the solvent in the metal ink on the substrate to form a metal organic layer with a predetermined pattern; treating, using oxygen plasma, the metal organic layer, to decompose the metal organic compounds of the metal organic layer into a corresponding metal and oxides of the metal; and treating, using hydrogen plasma, the metal organic layer treated by the oxygen plasma, so that the oxides of the metal are reduced to form the metal, and the metal electrode configured with the predetermined pattern is obtained.

In the method of manufacturing the metal electrode of the embodiment of the present application, the hydrophobic material comprises perfluorosilane.

In the method of manufacturing the metal electrode of the embodiment of the present application, the metal electrode comprises a copper electrode.

In the method of manufacturing the metal electrode of the embodiment of the present application, the metal organic compounds comprise at least one of copper-based metal organic compounds and copper micro/nanoparticles coated with organic compounds.

In the method of manufacturing the metal electrode of the embodiment of the present application, the metal electrode comprises a silver electrode.

In the method of manufacturing the metal electrode of the embodiment of the present application, the metal organic compounds comprise silver micro/nanoparticles coated with organic compounds.

The present application using the inkjet printing technology in combination with the plasma technology to manufacture the metal electrode has advantages of simplicity and convenience, material saving, high processing accuracy, and being controllable in profiles, and can effectively convert the metal oxides of the metal electrode to the corresponding metal, which is beneficial to obtain the metal electrode with high electrical conductivity. Because of high accuracy printing of the inkjet printing technology, the metal organic layer with the predetermined pattern of high dimensional accuracy can be directly obtained, and waste of materials can be avoided. In addition, since high-energy oxygen plasma can generate a local thermal field in a short time, the metal organic compounds in the metal organic layer can be decomposed into a corresponding metal and metal oxides, and then the hydrogen plasma is used to reduce the metal oxides to the corresponding metal, thereby obtaining the metal electrode with the predetermined pattern. Furthermore, the thermal field generated by the method only acts on the metal organic compounds, and has very little effect on the substrate, so the method is applicable to various substrates including flexible substrates, and is applicable to manufacturing of various display devices.

### BRIEF DESCRIPTION OF DRAWINGS

The following detailed description of specific embodiments of the present application will make the technical solutions and other beneficial effects of the present application obvious in conjunction with the accompanying drawings.

FIG. 1 is a flowchart of a method of manufacturing a metal electrode in accordance with an embodiment of the present application.

FIG. 2 is a schematic structural view showing a metal ink is printed by inkjet printing in accordance with an embodiment of the present application.

FIG. 3 is a schematic structural view of a vacuum chamber applied to plasma technology.

FIG. 4 is a schematic structural view of a metal electrode in accordance with an embodiment of the present application.

FIG. 5 is a flowchart of a method of manufacturing a copper electrode in accordance with an embodiment of the present application.

### DESCRIPTION OF PREFERRED EMBODIMENTS

The technical solutions in the embodiments of the present application will be clearly and completely described below with reference to the accompanying drawings in the embodiments of the present application. Obviously, the embodiments as described are only a part of the embodiments of the present application, but not all the embodiments. Based on the embodiments of the present application, all other embodiments obtained by those skilled in the art without creative work fall into the protection scope of the present application.

In the description of the present application, it is to be understood that the term “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, and the like indicates orientation or the orientation or positional relationship based on the positional relationship shown in the drawings, for convenience of description only and the present application is to simplify the description, but does not indicate or imply that the device or element referred to must have a particular orientation in a particular orientation construction and operation, and therefore not be construed as limiting the present application. Additionally, the terms “first” and “second” and the like are used for descriptive purposes only and are not to be construed as indicating or implying relative importance. Thus, features defining “first” or “second” may include one or more of the described features either explicitly or implicitly. In the description of the present application, the meaning of “a plurality” is two or more unless specifically and specifically defined otherwise.

In the present application, unless otherwise explicitly specified or limited, the terms “mounted”, “linked”, “connected”, and like terms are to be broadly understood. For example, it may be a fixed connection, a detachably connection, or an integrally connection, or may be a mechanical connection, electrically connection, or a directly connection. Alternatively, it can also be connected indirectly through intervening structures, or may be interaction between the two internal communicating elements or two elements. Those of ordinary skill in the art, to be understood that the specific meanings in the present application in accordance with specific circumstances.

In the present application, unless otherwise expressly specified or limited, the first feature being “on” or “lower” the second feature may include direct contact of the first and the second features and may also include that the first and the second features are not in direct contact, but in contact by the additional features therebetween. Also, the first feature being “on”, “above”, “upper” the second feature may include that the first feature is obliquely upward, directly above the second feature, or simply represent that a level of the first feature is higher than that of the second feature. The first feature being “beneath”, “below” and “lower” the second feature may include that the first feature is obliquely downward and right below the second feature, or simply represent that a level of the first feature is less than that of the second feature.

The following disclosure provides many different embodiments or examples to achieve different structures of the present application. To simplify the disclosure of the present application, the components and configuration of specific examples are described hereinafter. Of course, they are only illustrative, and are not intended to limit the present invention. Further, the present disclosure may repeat reference numerals in different embodiments and/or the reference letters. This repetition is for the purpose of simplicity and clarity, and does not indicate a relationship between the various embodiments and/or set in question. Further, the present application provides various specific examples of materials and processes, but one of ordinary skill in the art may be appreciated that other processes and applications and/or other materials.

The application is further described below with reference to the drawings and embodiments.

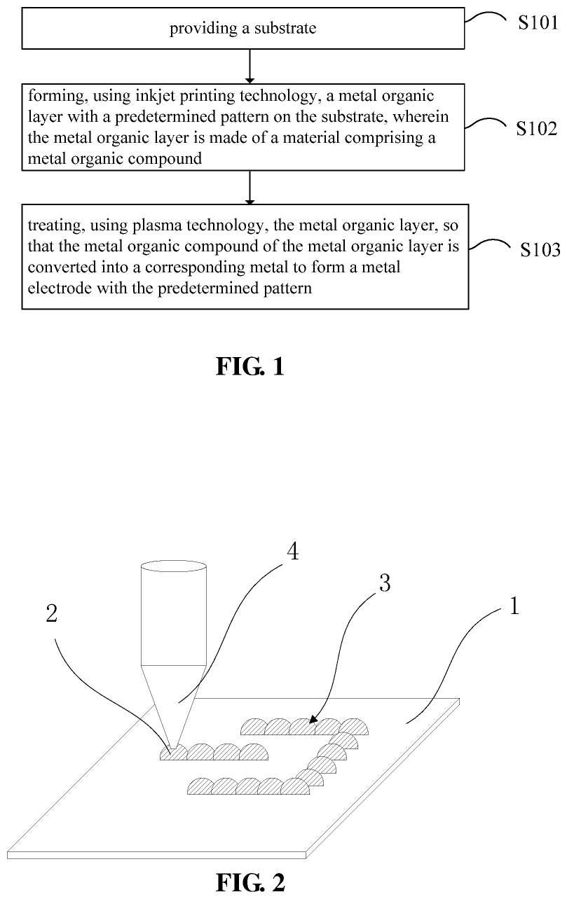

As show in FIG. 1, in one embodiment, the present application provides a method of manufacturing a metal electrode, including the following steps:

S101: providing a substrate.

Specifically, in order to prevent a metal ink from diffusing on the substrate in a next inkjet printing process (improving printing accuracy), it is necessary to use a hydrophobic material to hydrophobicize a surface to be printed on the substrate. The hydrophobic material includes perfluorosilane. Certainly, the hydrophobic material is not limited thereto.

S102: using inkjet printing technology to form a metal organic layer with a predetermined pattern on the substrate, wherein the metal organic layer is made of a material including metal organic compounds.

Specifically, as shown in FIG. 2, step S102 includes the following steps: printing a metal ink 2 on the substrate 1 according to a predetermined path, wherein the metal ink 2 includes the metal organic compounds and a solvent; and removing the solvent in the metal ink 2 on the substrate 1 by heating the substrate 1 after printing to form the metal organic layer 3 with the predetermined pattern.

Specifically, when a width of the metal organic layer 3 is determined, a height of the metal organic layer 3 mainly depends on a concentration of the metal ink 2. The higher the concentration of the metal ink is, the higher the height of the metal organic layer 3 is, and the higher the height of a metal electrode finally obtained is.

S103: using plasma technology to treat the metal organic layer, so that the metal organic compounds of the metal organic layer are converted into a corresponding metal to form a metal electrode with the predetermined pattern.

Specifically, as shown in FIGS. 2 and 4, step S103 includes the following steps: using oxygen plasma to treat the metal organic layer 3 to decompose the metal organic compounds of the metal organic layer 3 into the corresponding metal and oxides of the metal; using hydrogen plasma to treat the metal organic layer 3 treated by the oxygen plasma, so that the oxides of the metal are reduced to form the metal, and a metal electrode 5 with the predetermined pattern is obtained.

In this embodiment, because of high accuracy printing of the inkjet printing technology, the metal organic layer 3 with the predetermined pattern of high dimensional accuracy can be directly obtained, and waste of materials can be avoided. In addition, since high-energy oxygen plasma can generate a local thermal field in a short time, the metal organic compounds in the metal organic layer 3 can be decomposed into a corresponding metal and metal oxides, and then the hydrogen plasma is used to reduce the metal oxides to the corresponding metal, thereby obtaining the metal electrode 5 with the predetermined pattern. Therefore, the use of the inkjet printing technology in combination with the plasma technology to manufacture the metal electrode 5 has advantages of simplicity and convenience, material saving, high processing accuracy, and being controllable in profiles, and can effectively convert the metal oxides of the metal electrode 5 to the corresponding metal, which is beneficial to obtain the metal electrode 5 with high electrical conductivity.

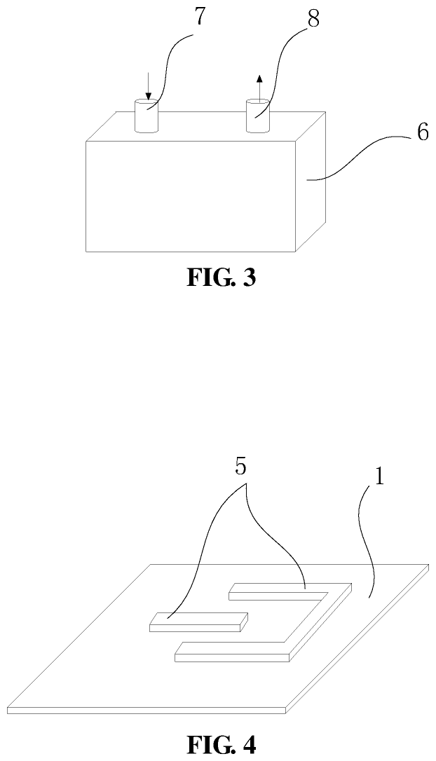

In one embodiment, as shown in FIGS. 2 and 3, the step of treating the metal organic layer using oxygen plasma to decompose the metal organic compounds of the metal organic layer into the corresponding metal and oxides of the metal includes the following steps:

placing the substrate 1 with the metal organic layer 3 in a vacuum chamber 6;
providing the oxygen plasma into the vacuum chamber 6; and
using the oxygen plasma to decompose the metal organic compounds of the metal organic layer 3 into the corresponding metal and the oxides of the metal.

Specifically, as shown in FIG. 3, the vacuum chamber 6 includes an inlet 7 and an outlet 8, and the oxygen plasma enters the vacuum chamber 6 from the inlet 7 to allow the substrate 1 configured with the metal organic layer 3 to be completely exposed to the oxygen plasma, wherein high-energy oxygen plasma generates local thermal field decomposition and melts the metal organic compounds in a short time, thereby generating an organic gas, metals, and metal oxides. The organic gas and excess oxygen plasma can be discharged from the outlet 8 of the vacuum chamber 6. The inlet 7 and the outlet 8 of the vacuum chamber 6 are provided at both ends of an upper surface of the vacuum chamber 6. Certainly, the inlet 7 and the outlet 8 can also be provided at other positions, which are not limited here.

Specifically, since the metal ink 2 also includes a dispersant, and the dispersant is an organic substance and will also be converted into an organic gas under an action of the thermal field generated by the oxygen plasma and discharged from the outlet 8 of the vacuum chamber 6.

In this embodiment, the treatment of the metal organic layer 3 by the oxygen plasma is completed in the vacuum chamber 6. The high-energy oxygen plasma converts all the organic compounds in the metal organic layer 3 into organic gas and discharges the gas, and forms a target metal and the oxides of the metal, which lays a foundation for a next operation, and improves purity of the electrode, and is convenient to operate, without loss of material.

In one embodiment, as shown in FIGS. 3 and 4, the step of using hydrogen plasma to treat the metal organic layer treated by the oxygen plasma, so that the oxides of the metal are reduced to form the metal includes the following steps:

stopping providing the oxygen plasma into the vacuum chamber 6;
providing the hydrogen plasma into the vacuum chamber 6; and using the hydrogen plasma to reduce the oxides of the metal to form the metal.

Specifically, the oxygen plasma enters the vacuum chamber 6 from the inlet 7 to allow the substrate 1 configured with the metal organic layer 3 to be completely exposed to the oxygen plasma.

In this embodiment, oxides of the metal formed after the oxygen plasma treatment are converted into the corresponding metal under the reducing action of the hydrogen plasma, so that the metal electrode 5 as required is obtained. This reduction process effectively reduces the presence of metal oxides, so that the metal electrode 5 obtained has a higher electrical conductivity.

In one embodiment, the substrate 1 includes any one of a glass substrate, a silicon wafer substrate, and a flexible substrate. Specifically, the flexible substrate is made of a material including any one of polyimide (PI), polyethylene terephthalate (PET), and polyethylene terephthalate (PEN). In this embodiment, the thermal field generated by the plasma technology only acts on the metal organic layer 3, and has very little effect on the substrate 1, and does not damage the structure of the substrate 1. As a result, the above-mentioned method of manufacturing a metal electrode is applicable to various substrates, including flexible substrates. Therefore, the above-mentioned method of manufacturing a metal electrode can be used to manufacture a metal electrode required for a flexible device. The manufacturing method will show great application value in fields such as flexible display panels.

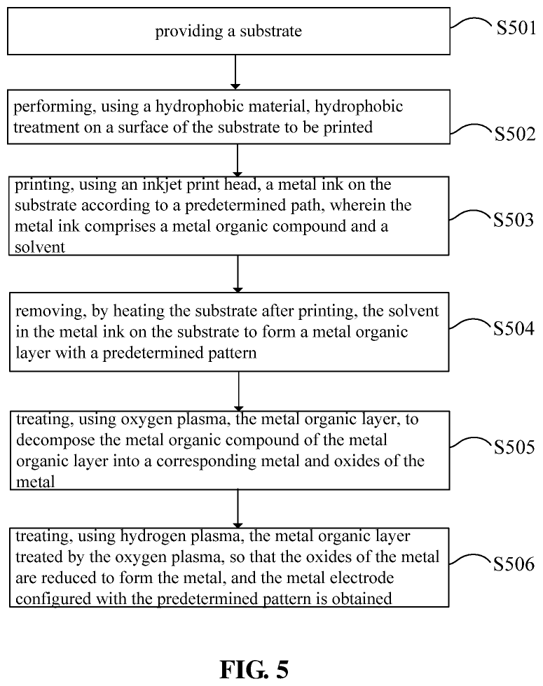

As shown in FIG. 5, in one embodiment, the present application provides a method of manufacturing a copper electrode, including the following steps:

S501: providing a substrate.

S502: using a hydrophobic material to perform hydrophobic treatment on a surface of the substrate to be printed, wherein the hydrophobic material includes perfluorosilane.

S503: using an inkjet print head to print a copper ink on the substrate according to a predetermined path, wherein the copper ink includes metal organic compounds and a solvent, wherein the metal organic compounds include at least one of copper-based metal organic compounds and copper micro/nanoparticles coated with organic compounds.

S504: heating the substrate after printing to remove the solvent in the metal ink on the substrate to form a metal organic layer with a predetermined pattern, wherein the metal organic layer is made of a material including the metal organic compounds.

S505: using oxygen plasma to treat the metal organic layer to decompose the metal organic compounds of the metal organic layer into a corresponding metal and oxides of the metal.

S506: using hydrogen plasma to treat the metal organic layer treated by the oxygen plasma, so that the oxides of the metal are reduced to form the metal, and the metal electrode configured with the predetermined pattern is obtained.

In this embodiment, copper metal has gradually become a main material of metal electrodes in display devices due to its advantages such as high electrical conductivity, low resistance, and low cost. In comparison with etching techniques for manufacturing the copper electrode, the present application using the inkjet printing technology in combination with the plasma technology convenient for use to manufacture the metal electrode has advantages of simplicity and convenience, material saving, high processing accuracy, and being controllable in profiles, and being beneficial to obtain a copper metal electrode with high electrical conductivity.

In one embodiment, the present application further provides a method of manufacturing a silver electrode (not shown). Steps of the method of manufacturing the silver electrode are the same as those of the method of manufacturing the copper electrode, and are not described here. A difference from the above embodiments lies in that a metal ink used to manufacture the silver electrode is a silver ink, and a material of the silver ink includes silver micro/nanoparticles (metal organic compounds) coated with organic compounds, a dispersant, and a solvent.

In this embodiment, the silver electrode has been a material of metal electrodes commonly used in display devices due to its high electrical conductivity. The present application using the inkjet printing technology in combination with the plasma technology convenient for use to manufacture the metal electrode has advantages of simplicity and convenience, material saving, high processing accuracy, and being controllable in profiles, and being beneficial to obtain a silver metal electrode with high electrical conductivity.

Accordingly, although the present application has been disclosed as a preferred embodiment, it is not intended to limit the present application. Those skilled in the art without departing from the spirit and scope of the present application may make various changes or modifications, and thus the scope of the present application should be after the appended claims and their equivalents.

What is claimed is:

1. A method of manufacturing a metal electrode, comprising:
providing a substrate;
forming, using inkjet printing technology, a metal organic layer with a predetermined pattern on the substrate, wherein the metal organic layer is made of a material comprising metal organic compounds; and
treating, using plasma technology, the metal organic layer, so that the metal organic compounds of the metal organic layer are converted into a corresponding metal to form a metal electrode with the predetermined pattern.

2. The method of manufacturing the metal electrode of claim 1, wherein the forming, using inkjet printing technology, a metal organic layer with a predetermined pattern on the substrate comprises:
printing, using an inkjet print head, a metal ink on the substrate according to a predetermined path, wherein the metal ink comprises the metal organic compounds and a solvent; and
removing, by heating the substrate after printing, the solvent in the metal ink on the substrate to form the metal organic layer with the predetermined pattern.

3. The method of manufacturing the metal electrode of claim 1, wherein the treating, using plasma technology, the metal organic layer, so that the metal organic compounds of the metal organic layer are converted into a corresponding metal comprises:
treating, using oxygen plasma, the metal organic layer, to decompose the metal organic compounds of the metal organic layer into the corresponding metal and oxides of the metal; and
treating, using hydrogen plasma, the metal organic layer treated by the oxygen plasma, so that the oxides of the metal are reduced to form the metal.

4. The method of manufacturing the metal electrode of claim 3, wherein the treating, using oxygen plasma, the metal organic layer, to decompose the metal organic compounds of the metal organic layer into the corresponding metal and oxides of the metal comprises:
placing the substrate with the metal organic layer in a vacuum chamber;
providing the oxygen plasma into the vacuum chamber; and
decomposing, using the oxygen plasma, the metal organic compounds of the metal organic layer into the corresponding metal and the oxides of the metal.

5. The method of manufacturing the metal electrode of claim 4, wherein the treating, using hydrogen plasma, the metal organic layer treated by the oxygen plasma, so that the oxides of the metal are reduced to form the metal comprises:
stopping providing the oxygen plasma into the vacuum chamber;
providing the hydrogen plasma into the vacuum chamber; and
reducing, using the hydrogen plasma, the oxides of the metal to form the metal.

6. The method of manufacturing the metal electrode of claim 5, wherein the vacuum chamber includes an inlet and an outlet, and the oxygen plasma and the hydrogen plasma enter the vacuum chamber from the inlet, wherein an organic gas is further generated when the metal organic compounds are decomposed by the oxygen plasma, and the organic gas is discharged from the outlet.

7. The method of manufacturing the metal electrode of claim 1, wherein the forming, using inkjet printing technology, a metal organic layer with a predetermined pattern on the substrate further comprises:
performing, using a hydrophobic material, hydrophobic treatment on a surface of the substrate to be printed.

8. The method of manufacturing the metal electrode of claim 7, wherein the hydrophobic material comprises perfluorosilane.

9. The method of manufacturing the metal electrode of claim 1, wherein the metal electrode comprises a copper electrode.

10. The method of manufacturing the metal electrode of claim 9, wherein the metal organic compounds comprise at least one of copper-based metal organic compounds and copper micro/nanoparticles coated with organic compounds.

11. The method of manufacturing the metal electrode of claim 1, wherein the metal electrode comprises a silver electrode.

12. The method of manufacturing the metal electrode of claim 11, wherein the metal organic compounds comprise silver micro/nanoparticles coated with organic compounds.

13. The method of manufacturing the metal electrode of claim 1, wherein the substrate comprises one of a glass substrate, a silicon wafer substrate, and a flexible substrate.

14. The method of manufacturing the metal electrode of claim 11, wherein the flexible substrate is made of a material comprising polyimide, polyethylene terephthalate, and polyethylene terephthalate.

15. A method of manufacturing a metal electrode, comprising:
providing a substrate;
performing, using a hydrophobic material, hydrophobic treatment on a surface of the substrate to be printed;
printing, using an inkjet print head, a metal ink on the substrate according to a predetermined path, wherein the metal ink comprises metal organic compounds and a solvent;
removing, by heating the substrate after printing, the solvent in the metal ink on the substrate to form a metal organic layer with a predetermined pattern;
treating, using oxygen plasma, the metal organic layer, to decompose the metal organic compounds of the metal organic layer into a corresponding metal and oxides of the metal; and
treating, using hydrogen plasma, the metal organic layer treated by the oxygen plasma, so that the oxides of the metal are reduced to form the metal, and the metal electrode configured with the predetermined pattern is obtained.

16. The method of manufacturing the metal electrode of claim 15, wherein the hydrophobic material comprises perfluorosilane.

17. The method of manufacturing the metal electrode of claim 15, wherein the metal electrode comprises a copper electrode.

18. The method of manufacturing the metal electrode of claim 17, wherein the metal organic compounds comprise at least one of copper-based metal organic compounds and copper micro/nanoparticles coated with organic compounds.

19. The method of manufacturing the metal electrode of claim 15, wherein the metal electrode comprises a silver electrode.

20. The method of manufacturing the metal electrode of claim 19, wherein the metal organic compounds comprise silver micro/nanoparticles coated with organic compounds.
